(19) United States
(12) Patent Application Publication
(10) Pub. No.: US 2008/0014872 A1
(43) Pub. Date: Jan. 17, 2008

(54) Method and device for reducing exposure to undesirable electromagnetic radiation

(75) Inventors: Kevin B. Tucek, Mesa, AZ (US); George Leger, Mesa, AZ (US); Steven C. Shanks, Mesa, AZ (US)

Correspondence Address: ETHERTON LAW GROUP, LLC, 5555 E. VAN BUREN STREET, SUITE 100, PHOENIX, AZ, 85008, US

(73) Assignee: Erchonia Patent Holdings, LLC

(21) Appl. No.: 11/487,045

(22) Filed: Jul. 14, 2006

(51) Int. Cl. H03C 1/52; H04B 1/04

(52) U.S. Cl. 455/106; 455/575.5; 455/114.1

(57) ABSTRACT

The present invention is a method and device for reducing exposure to undesirable electromagnetic radiation. The device uses a target antenna to capture certain radiation from an active emission source, such as a cell phone when it is transmitting or a microwave oven when it is cooking. The target antenna is tuned to the frequencies of the undesirable radiation emitted from the emission source. The device converts the captured radiation into an electric current, and dissipates the collected current by spending it to operate a thermal, mechanical, or electrical device. In the preferred embodiment, the current is directed to an LED display that lights up when supplied with the current, serving a secondary purpose of showing the user that the device is working.

### FIELD OF INVENTION

This invention relates generally to antennas that receive electromagnetic radiation. This invention relates more specifically to antennas adapted to be placed in the vicinity of an active electromagnetic radiation emission source to reduce undesirable radiation that emanates from the active emission source.

### BACKGROUND

Many devices transmit electromagnetic radiation when in operation. For example, wireless communication devices intentionally emanate electromagnetic radiation when transmitting. Other devices transmit inadvertently, for example when a microwave oven is cooking, microwaves may inadvertently escape the oven. The widespread acceptance and use of hand-held, portable cellular telephones has been accompanied by increasing concern regarding possible harmful effects of such radiation. Hand-held cellular telephones typically have an elongated housing with an antenna extending upward vertically from the housing. In use of this type of telephone, the user's head comes into close proximity to the antenna when his head is placed adjacent to the cell phone. The antenna emanates radiation when the cell phone is transmitting, and such an antenna is referred to herein as a transmitting antenna. Thus, when the user is talking, the device is emanating radiation from the transmitting antenna, and a substantial amount of electromagnetic energy is projected directly onto the user's head at close range.

Each cell phone has to meet certain government guidelines as to the amount of radiation the user is exposed to. The amount of RF radiation absorbed by the body is measured in units known as SARs, or specific absorption rates. It would be desirable to reduce the SARs without significantly adversely affecting the operation of the telephone.

There have been attempts to shield the body from the electromagnetic energy emanating from the transmitting antenna. For example, U.S. Pat. No. 5,613,221 issued to Hunt discloses a conductive strip placed between the transmitting antenna and the user's head, to conduct radiation away from the user's head. There have also been some attempts to move the source of electromagnetic energy away from the body by changing the transmitting antenna location or radiation pattern. For example, U.S. Pat. No. 6,356,773 issued to Rinot removes the transmitting antenna from the phone and places it atop the user's head. An insulating shield is disposed between the transmitting antenna and the user's head, like a cap, for blocking emissions so that they do not penetrate through to the user. U.S. Pat. No. 6,031,495 issued to Simmons et alia uses a conducting strip between two poles of a transmitting antenna to create an end fire bi-directional pattern away from the user's head. Others have-tried to reduce exposure to harmful emission by canceling the radiation. For example, U.S. Pat. No. 6,314,277 issued to Hsu et alia, is a cell phone antenna that cancels transmitted radiation of the cell phone with an absorbent directional shield by feeding the signal back into the cell phone.

Therefore, it is an object of this invention to provide a method and device for decreasing the SARs to the user of an active emission source without significantly adversely affecting the desired performance of the emission source. It is a particular object to provide a method and device for reducing the undesirable radiation a user is exposed to from a cell phone. It is a further object to provide a method and device for reducing undesirable radiation from an existing emission source that does not require connecting to or redesigning the emission source.

### SUMMARY OF THE INVENTION

The present invention is a method and device for reducing exposure to undesirable electromagnetic radiation. The device uses a target antenna to capture certain radiation from an active emission source, such as a cell phone when it is transmitting or a microwave oven when it is cooking. The target antenna is tuned to the frequency of the undesirable radiation emitted from the emission source. The device converts the captured radiation into an electric current, and dissipates the collected current by spending it to operate a thermal, mechanical, or electrical device. In the preferred embodiment, the current is directed to an LED display that lights up when supplied with sufficient current, thereby spending the collected current, and serving a secondary purpose of showing the user that the device is working.

### BRIEF DESCRIPTION OF THE DRAWINGS

FIG. 1 is a block diagram illustrating the present invention.

FIG. 2 is a block diagram illustrating the present invention near an emission source.

FIG. 3 is a perspective view of a cell phone with the present invention adhered to the outside shell.

FIG. 4 is a perspective view of a microwave oven with the present invention adhered to the outside housing.

FIG. 5 is a perspective view of a microwave oven with the present invention resting near it.

FIG. 6 is a block diagram of a printed circuit board of a preferred embodiment of the present invention for use with a cell phone.

### DETAILED DESCRIPTION OF THE INVENTION

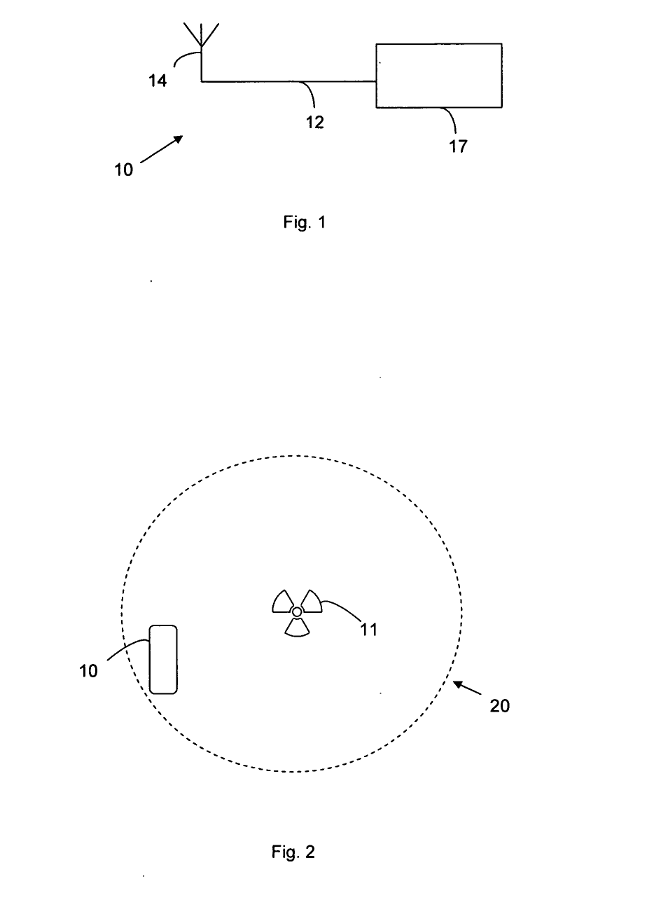

The present invention, referred to generally as 10, reduces undesirable radiation. It comprises a target antenna 14 and a dissipation assembly 17. See FIG. 1. The target antenna is tuned to the frequency of a nearby active emission source 11. Tuning the target antenna 14 comprises choosing the proper length antenna to correspond to the undesired wavelength of the emitted radiation. When the emission source 11 is in operation it transmits electromagnetic radiation. When target antenna 14 is bombarded by the radiation, electrons are stirred up in the target antenna 14, generating an electron flow (current). At some point this current needs to be drained from the antenna or the antenna will no longer absorb radiation. This current is drained from the target antenna 14 with a conductor 12 and moved to a dissipation assembly 17, which spends the current by operating a electrical, mechanical or thermal device. For small emission sources, the current is small and the conductor may be as simple as a wire or printed circuit board lead. For larger emission sources, a heavier-duty conductor may be required.

An antenna, as used herein, is any conducting mass that functions as a receiver or collector of electromagnetic energy—the target antenna 14 herein does not intentionally transmit electromagnetic energy. Antennas have a number of important parameters, those of most interest include the gain, radiation pattern, bandwidth and polarization. In a receiving antenna, the applied electromagnetic field is distributed throughout the entire length of the antenna to receive the undesirable radiation. If the target antenna 14 that the signal strikes has a certain length relative to the wavelength of the received radiation, the induced current will be much stronger. The desired length of the antenna can be determined by using the well-known equation: (λ)(f)=c, where λ is the wavelength of the incident radiation, f is the frequency of the incident radiation. For example, if a signal at 2.4 GHz travels through the air, it completes a cycle in approximately 12 cm. If the signal strikes a 12 cm antenna or fractions of it (½ or ¼ or 1/16 wavelength=6 or 3 or 0.75 cm, respectively), then the induced current will be much higher than if the signal struck a target antenna that was not some appreciable fraction of the wavelength.

Typically, cellular phones and other wireless communications technologies (PCS, G3 or Blue Tooth) emit radiation in the radio or microwave ranges, or both, when transmitting. These and other consumer products often emit multiple wavelengths (frequencies). This means that the target antenna 14 must perform well over a range of frequencies. So, the goal must be to make the target antenna resonant in the middle of that range of frequencies, the range commonly referred to as the antenna's bandwidth. For example, the preferred embodiment of the device 10 is used to reduce harmful emissions from a cell phone. The preferred embodiment uses a ceramic RF antenna tuned to a frequency of 1.88/2.1 GHz and having a bandwidth of 100 MHz, such as Part Number 311-1232-1-ND from Digi-Key Corporation. However, the antenna may be made with any material, gain, radiation pattern, bandwidth and polarization as appropriate for the emission source.

While reducing the cell phone's transmission has the negative effect of reducing the signal transmitted to the cell repeater station, it has the positive effect of reducing the amount of harmful radiation the user is exposed to. Selecting the right antenna 14 enables significant levels of harmful radiation to be reduced while only negligibly affecting the transmitted signal (which can be amplified to the necessary level by the distant repeater station).

In addition to use with cell phones, the present invention may be used with other emission sources such as other wireless communication devices such as satellite phones, BlackBerrys® and other email-transmitting devices; microwave ovens; portable radios, music players, and video players; automatic garage door and building door openers; police radar guns; short-wave and other ham radios; televisions or other cathode ray tube and plasma displays; power transmission lines; radioactive chemicals; or any other emission source.

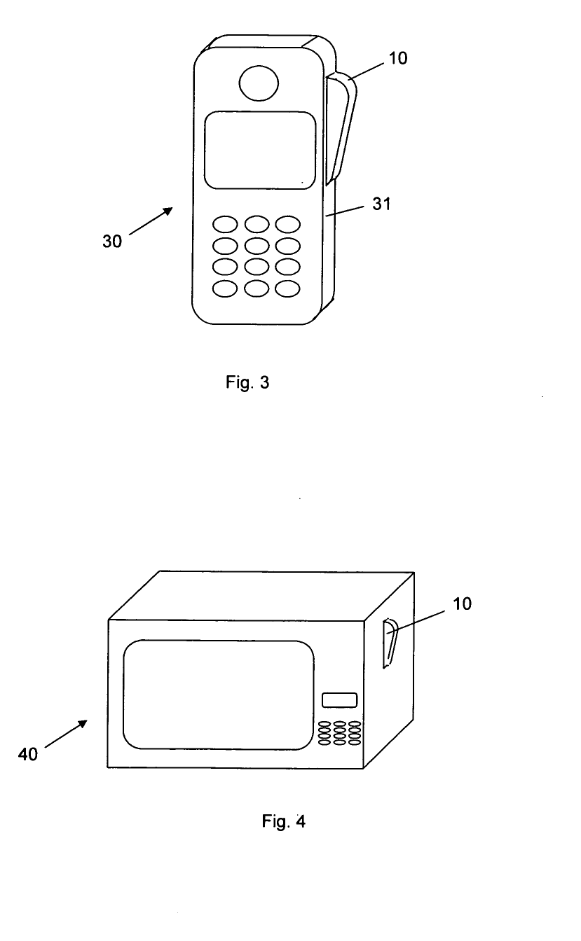

The device 10 does not have to be connected in any way to the emission source 11. And, in the preferred embodiment, the device 10 is not connected electrically to the emission source 11. However, in the preferred embodiment, the device 10 is connected physically to the emission source 11, simply so that the device 10 does not inadvertently get separated from the emission source 11 and stop functioning as intended. For example, the device 10 may be adhesively attached to the outer housing 31 of a cell phone 30, as shown in FIG. 3. The device 10 may be attached to the emission source 11 using other mechanisms, such as a screw, pin, compression or friction fit, for example, or the device 10 may be integrally formed with the emission source 11. Alternatively, the device 10 can be worn by the user, such as on a lanyard around the neck or pinned or clipped to clothing.

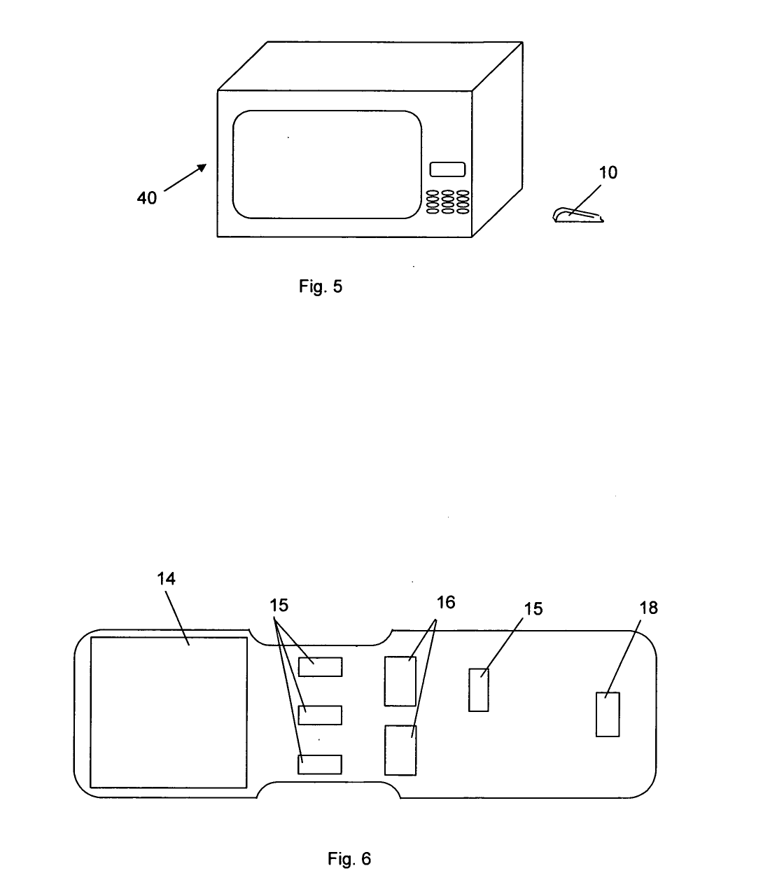

FIGS. 4 and 5 show the device 10 in conjunction with a microwave oven 40. As with the cell phone 30, the device 10 may be attached to the outer housing of the microwave oven 40, as shown in FIG. 4. Or, it may be desirable in some circumstances to not attach the device 10 to the emission source, for example when a microwave oven 40 is replaced regularly. In such case, the device may be separated from the emission source, as shown in FIG. 5. Regardless of whether the device 10 is physically attached or not, it must be within a certain distance to capture the undesirable radiation. This distance depends on a number of factors, including the emission frequency, power, medium through which the radiation is traveling, etc. The acceptable distance 20 is symbolically indicated in FIG. 2 with the dotted line.

The collected current can be used to operate any dissipation assembly 17, which is defined as one or more users of current. For example, the dissipation assembly 17 can be one or more of a buzzer, bell or any other transducer that converts electrical energy to sound; motor or any other transducer that converts electrical energy to motion; heater or any other transducer that converts electrical energy to heat; lamp or any transducer that converts electrical energy to light; or a combination thereof. The current may be used to catalyze a chemical reaction. In the preferred embodiment, the current is directed to an LED that lights up when supplied with the current, serving a secondary purpose of showing the user when the device 10 is working. In another embodiment, the current is directed to an LCD display. The dissipater assembly 17 may be used to operate one or more users of current within the emission source 11.

FIG. 6 illustrates the printed circuit board of a preferred embodiment used with a cell phone. This embodiment has been found to be effective in decreasing the SARs to the user of a cell phone without significantly adversely affecting the transmission from the cell phone to the cell tower, or base station. Target antenna 14 is connected to capacitors 15 and diodes 16, to drive the LED 18. The capacitors and diodes act as a voltage multiplier to generate sufficient voltage to drive the LED 18. For example, in this low-level application, four capacitors 15 are used with two diodes 16. Preferably the diodes 16 are high-frequency RF Schottky diodes, which have a very low forward voltage of about 0.2-0.3 V. Such diodes are available commercially from, for example, Aeroflex/Metelics, Inc. of Sunnyvale, Calif.

The number of capacitors and diodes can be increased or decreased as necessary when cooperating with emission sources of different levels of radiation. For example, when reducing undesirable emission from an emission sources emanating higher energy, such as short-wave radio, the number of capacitors can be reduced because the voltage draining off the antenna is itself sufficient to drive a dissipater assembly.

While there has been illustrated and described what is at present considered to be the preferred embodiment of the present invention, it will be understood by those skilled in the art that various changes and modifications may be made and equivalents may be substituted for elements thereof without departing from the true scope of the invention. Therefore, it is intended that this invention not be limited to the particular embodiment disclosed, but that the invention will include all embodiments falling within the scope of the appended claims.

I claim:

1. A method of reducing exposure to undesired electromagnetic radiation emanating from an active emission source, the method comprising:
a) receiving electromagnetic radiation from the active emission source at a target antenna whereby current is induced in the target antenna;
b) conducting the current to a dissipation assembly; and
c) operating the dissipation assembly with the current.

2. The method of claim 1 wherein the dissipation assembly comprises one ore more of an electrical, mechanical or thermal device.

3. The method of claim 1 wherein the dissipation assembly comprises a light emitting diode.

4. The method of claim 1 wherein the target antenna is tuned to the wavelength of the electromagnetic radiation emitted from the active emission source.

5. The method of claim 1 further comprising physically connecting the target antenna to the active emission source.

6. The method of claim 1 wherein the target antenna is not electrically connected to the active emission source.

7. The method of claim 1 wherein the active emission source is a cell phone.

8. The method of claim 7 wherein the radiation emanating from the cell phone is emitted from a transmitting antenna.

9. The method of claim 8 further comprising reducing SARs without significantly adversely affecting the signal transmitted by the cell phone.

10. The method of claim 1 wherein the active emission source is a microwave oven.

11. A device for reducing harmful electromagnetic radiation emanating from an active emission source, the device comprising:
a) a target antenna for receiving electromagnetic radiation emitted from the active emission source, and
b) a dissipation assembly connected to the target antenna.

12. The device of claim 11 wherein the dissipation assembly comprises one ore more of an electrical, mechanical or thermal device.

13. The device of claim 11 wherein the dissipation assembly comprises a light emitting diode.

14. The device of claim 11 wherein the target antenna is tuned to the wavelength of the electromagnetic radiation emitted from the active emission source.

15. The device of claim 11 further comprising physically connecting the target antenna to the active emission source.

16. The device of claim 11 wherein the target antenna is not electrically connected to the active emission source.

17. The device of claim 11 wherein the active emission source is a cell phone.

18. The device of claim 17 wherein the radiation emanating from the cell phone is emitted from a transmitting antenna.

19. The device of claim 18 further comprising reducing SARs without significantly adversely affecting the signal transmitted by the cell phone.

20. The device of claim 11 wherein the active emission source is a microwave oven.
